(19) United States
(12) Patent Application Publication
(10) Pub. No.: US 2014/0291145 A1
(43) Pub. Date: Oct. 2, 2014

(54) VACUUM PROCESSING APPARATUS

(71) Applicant: CANON ANELVA CORPORATION, Kawasaki-shi (JP)

(72) Inventors: Daisuke KOBINATA, Tokyo (JP); Masaaki ISHIDA, Kawasaki-shi (JP); Kyosuke SUGI, Fuchu-shi (JP); Naoki KUBOTA, Hino-shi (JP)

(21) Appl. No.: 14/303,837

(22) Filed: Jun. 13, 2014

Related U.S. Application Data
(63) Continuation of application No. PCT/JP2012/006058, filed on Sep. 24, 2012.

(30) Foreign Application Priority Data
Dec. 28, 2011 (JP) 2011-287445

(51) Int. Cl. H01J 37/32

(52) U.S. Cl. CPC H01J 37/32431
USPC 204/298.09

(57) ABSTRACT

A vacuum processing apparatus includes a substrate holder which can tilt relative to a target and includes a refrigerating machine which cools a substrate, hoses which transport a refrigerant between a compressor provided outside a vacuum vessel and a cooling device inside the substrate holder, and a housing unit which is provided outside the vacuum vessel and houses the hoses in a coiled state with a curvature radius that does not exceed a predetermined curvature radius.

This application is a continuation of International Patent Application No. PCT/JP2012/006058 filed on Sep. 24, 2012, and claims priority to Japanese Patent Application No. 2011-287445 filed on Dec. 28, 2011, the entire content of both of which is incorporated herein by reference.

### BACKGROUND OF THE INVENTION

1. Field of the Invention

The present invention relates to a vacuum processing apparatus and, more particularly, to a vacuum processing apparatus which can cool a substrate held by a substrate holder tiltably provided in a vacuum vessel.

2. Description of the Related Art

There is known a deposition apparatus designed to cool the substrate held by a substrate holder by using a GM refrigerating machine (see, for example, PTL 1). This deposition apparatus is configured to efficiently cool a substrate by placing the refrigerating machine in the substrate holder. A compressor which exchanges helium gas with the refrigerating machine is placed outside a vacuum chamber. The refrigerating machine is connected to the compressor through hoses which transport helium as a refrigerant.

### CITATION LIST

### Patent Literature

PTL 1: Japanese Patent Laid-Open No. 2011-149100

### SUMMARY OF THE INVENTION

### Technical Problem

According to the technique disclosed in PTL 1, the refrigerating machine needs to be tilted to tilt the substrate holder because of a structure in which the substrate holder incorporates the refrigerating machine. When tilting the refrigerating machine, the hoses coupled to the refrigerating machine bend in accordance with the tilt of the substrate holder. In this case, the hoses are formed from a flexible material but have a structure that can stand the high internal pressure generated by helium gas. That is, the hoses have the property of being susceptible to bending with a curvature radius smaller than a predetermined curvature radius. For this reason, when tilting the refrigerating machine, it is necessary to suppress the curvature radius of each hose to a value equal to or more than a predetermined value.

The present invention has been made in consideration of the above problem, and provides a vacuum processing apparatus which can cool the substrate held by a substrate holder which tilts in a vacuum vessel.

### Solution to Problem

A vacuum processing apparatus according to the present invention is comprising a vacuum vessel configured to internally perform a vacuum process, a target holder to which a target is configured to be attached, a substrate holder on which a substrate is held, a tilting unit configured to tilt a substrate held by the substrate holder relative to the target by making the substrate holder pivot about a pivot shaft when the target is attached to the target holder, a refrigerating machine provided in the substrate holder and configured to cool a substrate held by the substrate holder by operating together with a compressor provided outside the vacuum vessel, a transportation unit configured to transport a refrigerant between the compressor and the refrigerating machine, and a housing unit, provided outside the vacuum vessel, configured to house the transportation unit in a state in which a predetermined curvature radius is not exceeded, wherein the housing unit includes a coupling portion having one end portion coupled to the refrigerating machine and the other end portion coupled to the transportation unit at a position a predetermined distance away from the pivot shaft and configured to pivot accompanying pivoting operation of the substrate holder, and a first guide portion configured to guide the transportation unit while bending the transportation within a range which does not exceed a predetermined curvature radius accompanying pivoting operation of the coupling portion.

### Advantageous Effects of Invention

According to the vacuum processing apparatus of the present invention, it is possible to provide a vacuum processing apparatus which can cool the substrate held by a substrate holder which tilts in a vacuum vessel. Since this apparatus includes the substrate holder configured to cool a substrate by using a GM refrigerating machine, in particular, it is possible to sufficiently cool a substrate even in a vacuum process or apparatus configuration with a relatively large heat inflow while tilting the substrate.

Other features and advantages of the present invention will be apparent from the following description taken in conjunction with the accompanying drawings. Note that the same reference numerals denote the same or like components throughout the accompanying drawings.

### BRIEF DESCRIPTION OF THE DRAWINGS

The accompanying drawings, which are incorporated in and constitute a part of the specification, illustrate exemplary embodiments of the invention and, together with the description, serve to explain the principles of the present invention.

FIG. 1 is a schematic view of a vacuum processing apparatus according to the first embodiment of the present invention;

FIG. 2 is a sectional view taken along A-A in FIG. 1;

FIG. 3 is a sectional view taken along B-B in FIG. 1;

FIG. 4 is a view for explaining a state of hoses when a substrate holder according to the first embodiment of the present invention tilts;

FIG. 5 is a schematic view of a vacuum processing apparatus according to the second embodiment of the present invention; and

FIG. 6 is a view for explaining a state of hoses when a substrate holder according to the second embodiment of the present invention tilts.

### DESCRIPTION OF THE EMBODIMENTS

Each embodiment of the present invention will be described below with reference to the accompanying drawings. Obviously, the members, arrangements, and the like described below are merely examples for the implementation of the present invention but do not limit the invention, and can be variously modified in accordance with the spirit of the invention. Each embodiment will exemplify a sputtering apparatus as a vacuum processing apparatus 1. Obviously, however, the present invention can be applied to other types of deposition apparatuses and etching apparatuses.

### First Embodiment

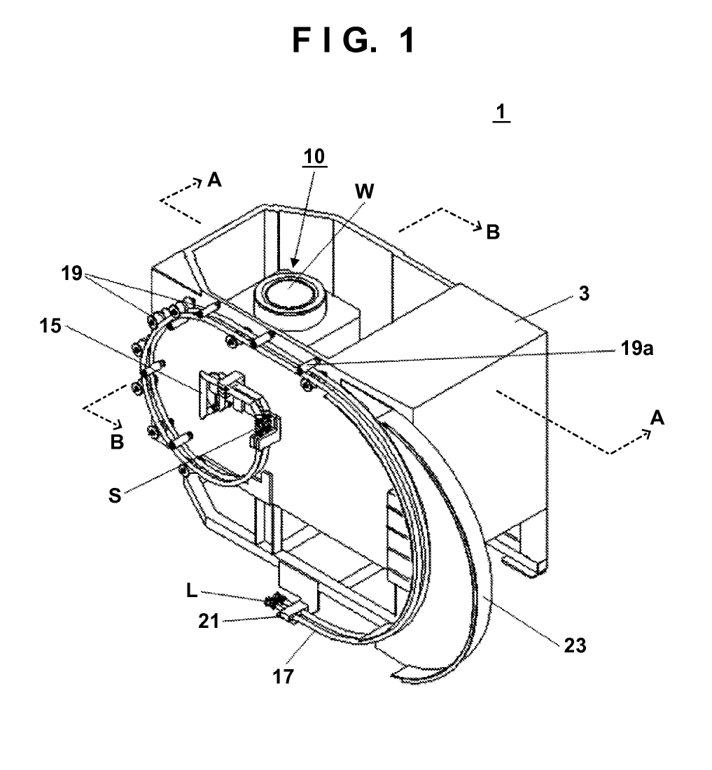

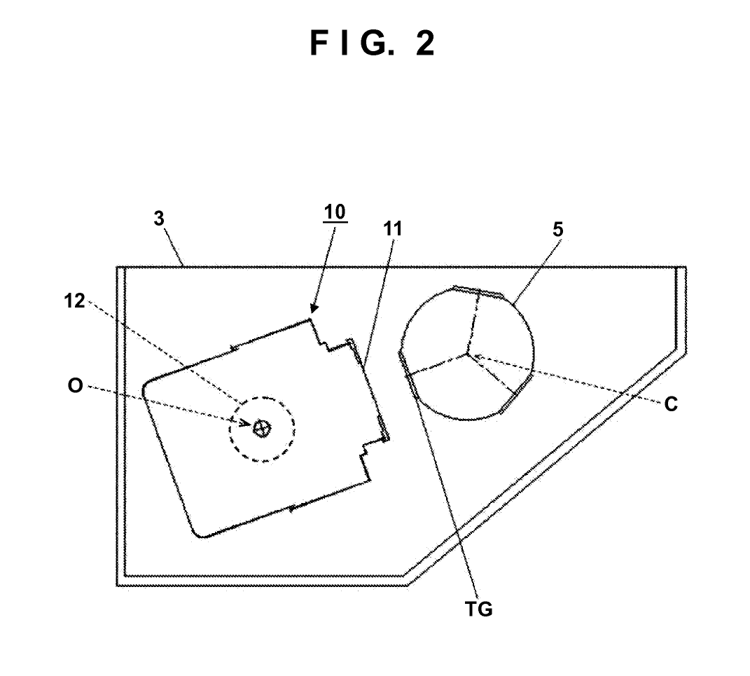

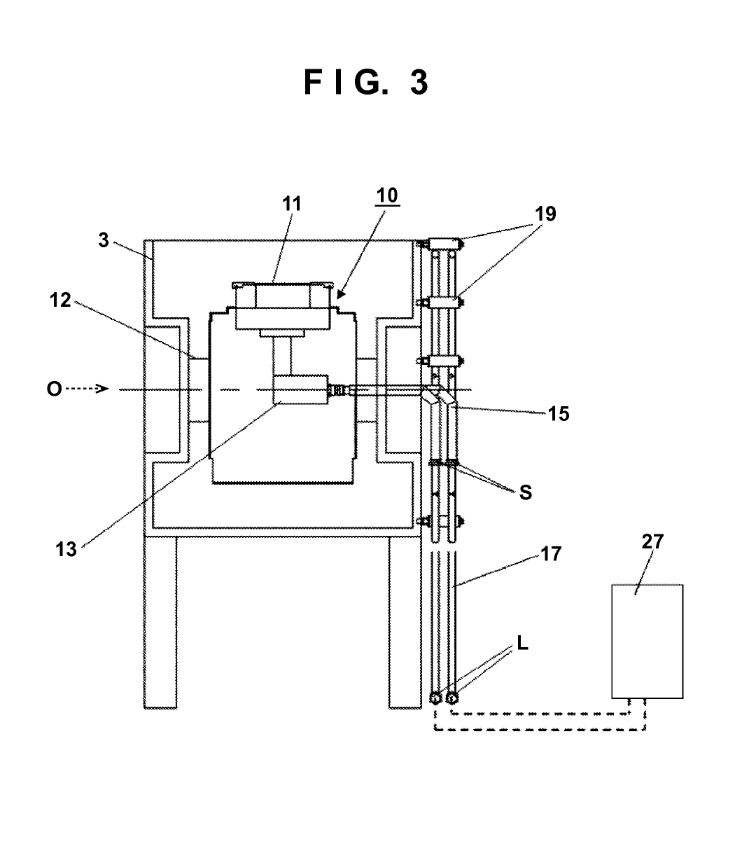

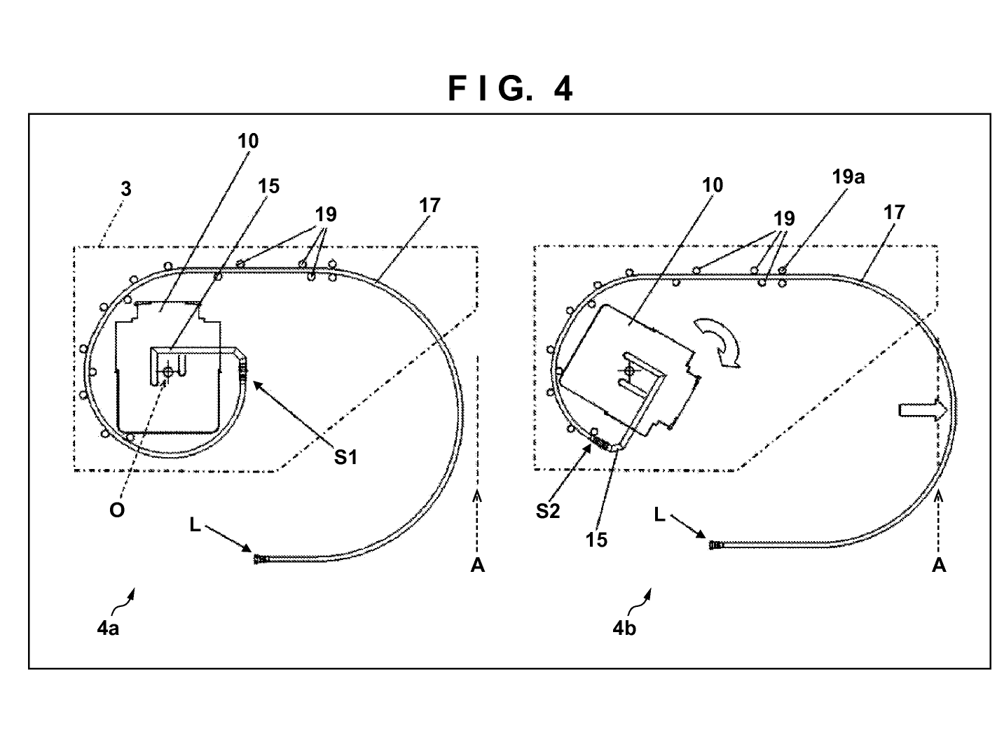

A vacuum processing apparatus according to the first embodiment will be described with reference to FIGS. 1 to 4. FIG. 1 is a schematic view of a vacuum processing apparatus 1. FIG. 2 is a sectional view taken along A-A in FIG. 1, and a schematic sectional view of a central portion of the vacuum processing apparatus 1 on a plane perpendicular to a holder pivot shaft O. FIG. 3 is a sectional view taken along B-B in FIG. 1, and a schematic sectional view of a substrate holder 10 on a plane in a gravity direction parallel to the holder pivot shaft O. In addition, FIG. 4 is a view for explaining a state of hoses 17 when the substrate holder 10 tilts.

The vacuum processing apparatus 1 is a sputtering apparatus. Tilting the substrate holder 10 relative to a cathode 5 (target holder) can change the angle (incident angle) at which a deposition material (sputtering particles) sputtered from a target TG of the cathode 5 strikes a substrate W. The vacuum processing apparatus 1 includes the substrate holder 10 and the cathode 5 inside a vacuum vessel 3.

The cathode 5 as a target holder is a rotating cathode which rotates about a cathode rotation axis C as a rotation axis. The three targets TG are attached to the outer circumferential portion of the cathode 5. It is possible to select the target TG to be used for film formation by making the target TG face the substrate holder 10. The cathode 5 incorporates a magnet which generates a magnetic field on the surface of the target TG. It is possible to sputter the selected target TG by applying power from a power supply (not shown) to the target TG facing the substrate holder 10. In addition, rotating the cathode 5 can change the relative angle of the target TG facing a substrate W held by the substrate holder 10. Therefore, rotating the cathode 5 can also change the angle at which the deposition material sputtered from the selected target TG strikes the substrate W. Making sputtering particles strike the substrate W at some angle can implement an even film thickness, or the like. A gas supply device (not shown) which supplies a process gas is provided around the cathode 5.

The substrate holder 10 includes a stage 11 (substrate stage) which holds the substrate W and is configured to be tiltable by using a tilting device which pivots about the holder pivot shaft O (pivot shaft). The tilting device causes the substrate holder 10 to pivot about the holder pivot shaft O, and can adjust the relative angle at which the substrate W on the stage 11 faces the target TG. The tilting device is a device which makes the substrate holder 10 pivot about the holder pivot shaft O, and includes a pivot member 12 which is coupled to the substrate holder 10 and pivots about the vacuum vessel 3. In addition to the pivot member 12, the tilting device includes a bearing which supports the pivot member 12 on the vacuum vessel 3, a sealing mechanism which seals the connecting portion between the pivot member 12 and the vacuum vessel 3, a drive source which makes the pivot member 12 pivot, a sensor which detects the tilt angle of the substrate holder 10 by detecting the pivot angle of the drive source, and a controller which controls the drive source based on a signal from the sensor and a set value input in advance. It is possible to arbitrarily adjust the relative angle (incident angle) at which sputtering particles from the target TG to the substrate W by adjusting the rotational angle of the cathode 5 and the tilting device.

The substrate holder 10 incorporates a refrigerating machine 13 as a cooling device which cools the stage 11. The refrigerating machine 13 is mounted in the substrate holder 10. The tilting device makes the refrigerating machine 13 pivot (tilt) together with the substrate holder 10. Note that the interior of the substrate holder 10 is hermetically sealed. This makes it possible to hold the interior of the substrate holder 10 at atmospheric pressure even if a vacuum atmosphere is set in the vacuum vessel 3.

The refrigerating machine 13 (cooling device) is a GM refrigerating machine. The GM refrigerating machine is a refrigerating machine which can cryogenically cool helium gas by the adiabatic expansion of the gas caused by vertically driving the piston (displacer) in the cylinder containing a cold storage agent inside the refrigerating machine. The refrigerating machine 13 is used (operated) together with a compressor 27. This embodiment uses helium gas as a refrigerant. As schematically shown in FIG. 3, the compressor 27 is placed outside the vacuum vessel 3. The refrigerating machine 13 cools the substrate W through the stage 11 coupled to the refrigerating machine 13 by expanding high-pressure helium gas (high-pressure refrigerant) supplied from the compressor 27 inside the cylinder. The compressor recovers the low-pressure helium gas (low-pressure refrigerant) expanded in the refrigerating machine and internally compresses the gas into high-pressure helium gas.

The refrigerating machine 13 is connected to the compressor through the hoses (transportation units) 17 which can transport high-pressure helium gas. The hoses 17 include a supply hose which supplies high-pressure helium gas from the compressor to the refrigerating machine 13 and a recovery hose which returns helium gas from the refrigerating machine 13 to the compressor. In addition, the refrigerating machine 13 is provided with coupling portions 15 respectively coupled to the two hoses 17. More specifically, the coupling portions 15 are coupled to transportation ports (not shown) communicating with the cylinder in the refrigerating machine 13. High-pressure helium gas is supplied from one transportation port into the cylinder through the coupling portion 15, and the low-pressure helium gas expanded in the cylinder is discharged from the other transportation port to the outside of the refrigerating machine 13. The coupling portions 15 are rigid metal tubular members, and pivot (tilt) accompanying the substrate holder 10.

Note that the curvature radius which the hoses 17 can endure when they bend in operation is larger than that when used in a fixed state. For this reason, the curvature radius of the hoses which repeatedly bend in operation needs to be controlled in a predetermined range. That is, when using the hoses 17 in the vacuum processing apparatus 1 while bending them, it is preferable to use them within the range of curvature radii which do not exceed a predetermined curvature radius that allows use with high durability.

A housing device (a housing unit) which houses the hoses 17 in a coiled state around the holder pivot shaft O is provided on a side surface of the vacuum vessel 3 which is located on the atmospheric side. The hoses 17, for example, rotate and bend upon tilting of the substrate holder 10. For this reason, the housing device is a device which prevents the hoses 17 from bending beyond a predetermined curvature radius regardless of the tilt state of the substrate holder 10 by restricting the curvature radius and routing of the hoses 17. The housing device also reduces friction and external stress when the hoses 17 move.

The housing device includes at least the coupling portions 15 and roller guides (first guide portions) 19. The hoses 17 are bent and wound in a coiled state in accordance with the pivoting direction of the substrate holder 10. In the arrangement shown in FIG. 1, the hoses 17 are wound clockwise because the substrate holder 10 pivots clockwise when it tilts relative to the target TG. Note that when the housing device is placed on the opposite side surface of the vacuum vessel 3 through which the holder pivot shaft O passes, the substrate holder pivots counterclockwise, and hence the hoses 17 are wound counterclockwise. Bending the hoses 17 in such a direction can house the hoses 17 in accordance with the dimensions of a side wall of the vacuum vessel 3. In addition, when the tilt angle of the substrate holder 10 is 0°, the hoses 17 have no slack. This facilitates maintenance work on the hoses 17.

As described above, the coupling portions 15 are tubular members coupled to the refrigerating machine 13, and are members which determine start point positions S of the routing of the hoses 17. In addition, the coupling portions 15 have strength to endure bending and stress in a twisting direction which are caused when the substrate holder 10 tilts. The refrigerating machine 13 is coupled to one end of the coupling portion 15. The hose 17 is coupled to the other end portion of the coupling portion 15. Note that the coupling portion 15 is coupled to the refrigerating machine 13 inside the vacuum vessel 3, whereas the coupling portion 15 is coupled to the hose 17 outside the vacuum vessel 3.

Rollers forming the roller guides 19 are cylindrical members supported on an outer wall surface of the vacuum vessel 3 through bearings. When the hoses 17 move in contact with the rollers, the rollers smoothly rotate to reduce the resistance to the hoses 17. This makes it possible to smoothly tilt the substrate holder 10. Support grooves for the hoses 17 are formed in portions of the rollers to prevent the hoses 17 from coming off a predetermined route.

The roller guide 19 as a first guide portion includes a plurality of rollers provided on an outer wall of the vacuum vessel 3 so as to be juxtaposed along the route along which the hoses 17 are routed and housed. The hoses 17 which move as the substrate holder 10 pivots with the help of the roller guides 19 are bent in a state in which they do not exceed a predetermined curvature radius, and guided and housed in a coiled state.

One end portion of the hose 17 is coupled to the coupling portion 15 at a position (start point position S) a predetermined distance away from the holder pivot shaft O in the radial direction. Therefore, one end portion of the hose 17 receives a force from the coupling portions 15 in a pivoting direction. The hose 17 housed in the housing device has a curvature radius equal to or more than the distance between the start point position S and the holder pivot shaft O. In this case, the distance (predetermined distance) between the start point position S and the holder pivot shaft 0 is determined to make the hose 17 have a curvature radius that allows use with sufficiently high durability.

A terminal fixing portion 21 (fixing portion) is fixed to an outer wall of the vacuum vessel 3 at a predetermined position on the vacuum vessel 3. The terminal fixing portion 21 is a member to which the opposite side of the hoses 17 coupled to the coupling portions 15 is connected, and is a member which determines an end point position L of the routing of the hoses 17 inside the housing device. The terminal ends of the hoses 17 fixed to the terminal fixing portion 21 are further connected to other hoses and connected to the compressor. The terminal fixing portion 21 fixes the end point position L of the hoses 17. For this reason, the hoses for the transportation of helium gas which are installed between the end point position L and the compressor do not move upon movement of the substrate holder 10. This facilitates the routing of the hoses.

A cover (cover member) 23 for protecting the route along which the hoses 17 is housed is provided on an outer wall of the vacuum vessel 3. The cover 23 protects the hoses 17 located between a terminal roller 19a of the roller guides 19 and the terminal fixing portion 21 so as to prevent the hoses 17 from deforming caused by unexpected external stress.

The operation of the housing device will be described with reference to FIG. 4. In FIGS. 4, 4a and 4b represent views for explaining the states of the hoses 17 when the tilt angle of the substrate holder 10 is 0° and 120°. The substrate holder 10 can be set at an arbitrary angle between tilt angles of 0° and 120°. The end point position L of the routing of the hoses 17 does not change regardless of the tilt angle of the substrate holder 10. When, however, the tilt angle changes from 0° to 120°, the start point position S of the routing of the hoses 17 moves from S1 to S2. The coupling portion 15 is a rigid member, and hence pivots in synchronism with the tilting operation of the substrate holder 10. For this reason, as the substrate holder 10 tilts, stress acts at the start point position S of the hoses 17 to move the position from S1 to S2. As the start point position S of the hoses 17 changes from S1 to S2, the hoses 17 move along the roller guides 19 while bending.

No roller is placed between the terminal roller 19a of the roller guides 19 and the terminal fixing portion 21. On this portion, the hoses 17 receive no stress from other members. As the start point position S of the hoses 17 changes, the length of the hoses 17 located between the terminal roller 19a and the terminal fixing portion 21 changes. That is, when the tilt angle of the substrate holder 10 is 0° (see 4a in FIG. 4), the position of the hoses 17 does not exceed a reference line A (see FIG. 4). When this tilt angle is 120° (see 4b in FIG. 4), the hoses 17 extend to a position exceeding the reference line A. The hoses 17 extending from the terminal roller 19a to the terminal fixing portion 21 have a curvature radius that allows use with high durability regardless of the tilt angle of the substrate holder 10. In addition, the hoses 17 guided by the roller guides 19 is made to have a curvature radius that allows use with high durability. That is, it is possible to house the hoses 17 in a bent state so as not to exceed a predetermined curvature radius regardless of the tilt angle of the substrate holder 10.

The present invention can provide the vacuum processing apparatus 1 which includes the GM refrigerating machine 13 in the substrate holder 10 to cool the substrate W held by the substrate holder 10 which is included in the vacuum vessel 3 so as to be tiltable relative to the target TG. The vacuum processing apparatus 1 uses a GM refrigerating machine as the refrigerating machine 13, and hence can sufficiently cool the substrate W in a vacuum process or apparatus configuration with a relatively large heat inflow while tilting the substrate W. In addition, the vacuum processing apparatus 1 can house the hoses 17 with a sufficiently high curvature radius, and hence can prolong maintenance intervals without imposing load on the hoses 17.

### Second Embodiment

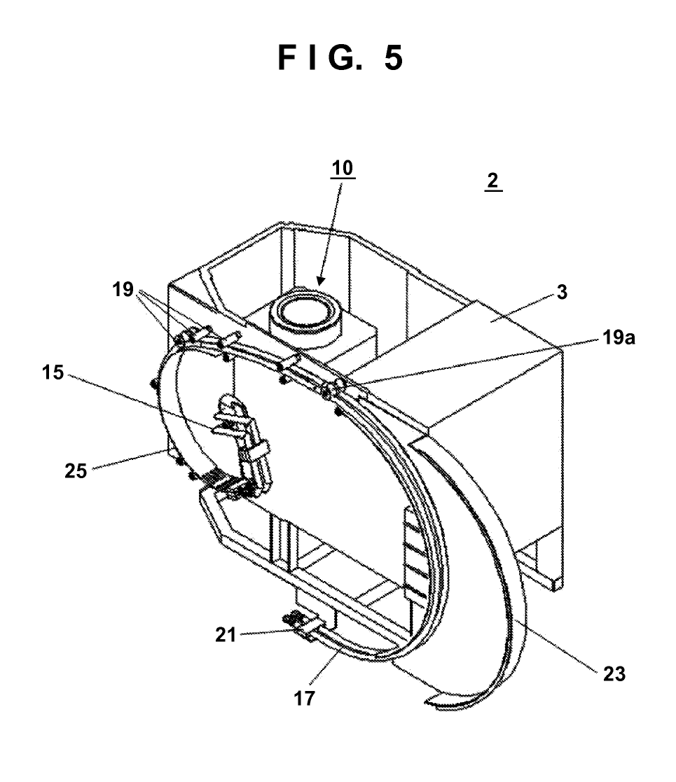

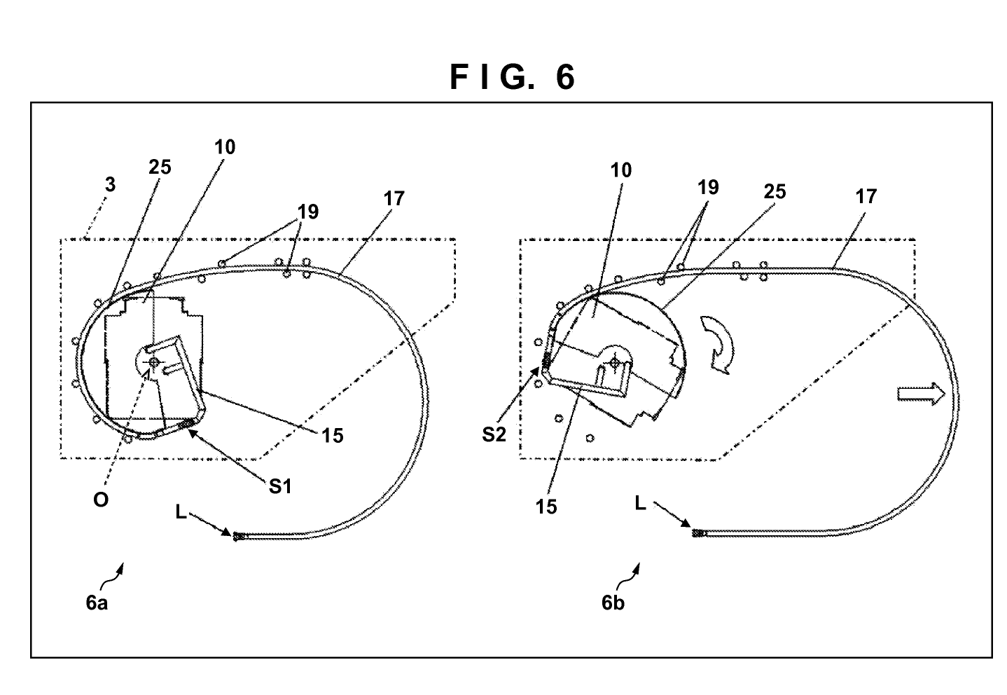

A vacuum processing apparatus according to the second embodiment will be described with reference to FIGS. 5 and 6. The same reference numerals as in the first embodiment denote the same constituent elements in the second embodiment, and a description of them will be omitted. This embodiment differs from the first embodiment in that a housing device of a vacuum processing apparatus 2 according to the second embodiment includes a rotating guide 25 (second guide portion) in place of some of the rollers.

The rotating guide 25 as the second guide portion is a plate-like member curved in an arc shape which pivots as coupling portions 15 tilt. The rotating guide 25 can guide hoses 17 by bringing the curved plate-like portion into contact with the hoses 17 in accordance with the tilt of a substrate holder 10. The rotating guide 25 is formed to have a curvature radius that allows the use of the hoses 17 with high durability. Some of the rollers constituting roller guides 19 (first guide portions) are provided at positions facing the rotating guide 25 through the hoses 17. The rotating guide 25 and the rollers guide the hoses 17. In addition, rollers are arranged on the two sides of the hoses 17 on the terminal fixing portion 21 side, as in the first embodiment, which serve as the roller guides 19 at a portion which does not face the rotating guide 25. Therefore, the rotating guide 25 guides the hoses 17 to the roller guides (first guide portions) 19.

In addition, fixing, to the rotating guide 25, portions of the hoses 17 which are located near the connecting portion with the coupling portions 15 can reduce bending stress acting on the connection portion between the hoses 17 and the coupling portions 15 when the substrate holder 10 tilts. In addition, when the roller guides 19 are installed, gaps are generated between the rollers. The curvature radius of the hoses 17 changes in this interval. However, using the rotating guide 25 can eliminate a change in the curvature radius of the hoses 17 between the rollers.

The effect of the rotating guide 25 will be described with reference to FIG. 6. It is possible to set the substrate holder 10 at an arbitrary angle between tilt angles of 0° and 120°. When the tilt angle of the substrate holder 10 is 0° (6a in FIG. 6), the hoses 17 are in contact with the most part of the plate-like portion of the rotating guide 25. For this reason, at the portion where the rotating guide 25 is placed, the curvature radius of the hoses 17 does not exceed that of the rotating guide 25. On the other hand, the hoses 17 near the connecting portions with the coupling portions 15 are fixed to the rotating guide 25. For this reason, when the tilt angle of the substrate holder 10 is 120° (6b in FIG. 6), the stress applied to the hoses 17 near the connecting portions with the coupling portions 15 does not change, and tilting the substrate holder 10 does not change the curvature of the hoses 17 near the connecting portions with the coupling portions 15. That is, it is possible to prevent the hoses 17 from being locally bent by the pivoting operation of the substrate holder 10.

The vacuum processing apparatus 2 of this embodiment has the same effects as those of the vacuum processing apparatus 1 described above. In particular, this makes it possible to reliably house the hoses 17 with sufficiently large curvature radius. In addition, it is possible to prevent the hoses 17 from being locally curved by the pivoting operation of the substrate holder 10. This makes it possible to prolong maintenance intervals.

The present invention is not limited to the above embodiments and various changes and modifications can be made within the spirit and scope of the present invention. Therefore, to apprise the public of the scope of the present invention, the following claims are made.

What is claimed is:

1. A vacuum processing apparatus comprising:
a vacuum vessel configured to internally perform a vacuum process;
a target holder to which a target is configured to be attached;
a substrate holder on which a substrate is held;
a tilting unit configured to tilt a substrate held by said substrate holder relative to the target by making said substrate holder pivot about a pivot shaft when the target is attached to said target holder;
a refrigerating machine provided in said substrate holder and configured to cool a substrate held by said substrate holder by operating together with a compressor provided outside said vacuum vessel;
a transportation unit configured to transport a refrigerant between the compressor and said refrigerating machine; and
a housing unit, provided outside said vacuum vessel, configured to house said transportation unit in a state in which a predetermined curvature radius is not exceeded,
wherein said housing unit includes a coupling portion having one end portion coupled to said refrigerating machine and the other end portion coupled to said transportation unit at a position a predetermined distance away from the pivot shaft and configured to pivot accompanying pivoting operation of said substrate holder, and
a first guide portion configured to guide said transportation unit while bending said transportation within a range which does not exceed a predetermined curvature radius accompanying pivoting operation of the coupling portion.

2. The vacuum processing apparatus according to claim 1, further comprising a fixing portion configured to fix one end portion of said transportation unit at a predetermined position outside said vacuum vessel.

3. The vacuum processing apparatus according to claim 1, further comprising a second guide portion configured to pivot accompanying tiling operation of the substrate and guide said transportation unit so as to make said first guide portion guide said transportation unit.

4. The vacuum processing apparatus according to claim 1, wherein said transportation unit bends in a pivoting direction when said substrate holder pivots.
